(19) United States
(12) Patent Application Publication
(10) Pub. No.: US 2017/0054069 A1
(43) Pub. Date: Feb. 23, 2017

(54) PIEZOELECTRICITY PVDF MATERIALS AND METHOD FOR MAKING THE SAME

(71) Applicant: Mehmet Bayindir, Ankara (TR)

(72) Inventors: Mehmet Bayindir, Ankara (TR); Mehmet Kanik, Ankara (TR)

(73) Assignee: Mehmet Bayindir, Ankara (TR)

(21) Appl. No.: 14/828,524

(22) Filed: Aug. 18, 2015

(51) Int. Cl. H01L 41/193; B29B 11/04; H01L 41/333; B29B 13/00; B29C 67/20; B29C 55/00; B29B 11/14

(52) U.S. Cl. CPC H01L 41/193; B29C 55/005; B29B 11/04; B29B 11/14; B29B 13/00; B29C 67/202; H01L 41/333; B29B 2013/005; B29K 2027/16

(57) ABSTRACT

This invention provides kilometer-long, endlessly parallel, spontaneously piezoelectric and thermally stable poly(vinylidene fluoride) (PVDF) ribbons using iterative size reduction technique based on thermal fiber drawing method. The PVDF ribbons are thermally stable and conserve the polar γ phase even after being exposed to heat treatment above the melting point of PVDF. A single PVDF ribbon has an average effective piezoelectric constant as −58.5 pm/V. PVDF ribbons in the invention are promising structures for constructing devices such as highly efficient energy generators, large area pressure sensors, artificial muscle and skin, due to the unique geometry and extended lengths, high polar phase content, high thermal stability and high piezoelectric coefficient.

### TECHNICAL FIELD OF THE INVENTION

This invention relates to piezoelectricity materials and a method for making the piezoelectricity materials,and particularly, to Poly (vinylidene fluoride) piezoelectricity materials and method for making the same.

### BACKGROUND

Utilization of the unique material properties by flexible, lightweight and biocompatible piezoelectric polymeric materials such as poly (vinylidene fluoride) (PVDF) and its copolymer poly (vinylidene fluoride trifluoroethylene) (PVDF-TrFE) is expected to bring on new horizons for sensor, actuator, and energy harvesting applications where piezoelectric ceramic materials have been employed hitherto. A closer look into the applications of piezoelectricity including biosensing, energy generation, pressure sensing, high precision positioning, artificial muscle and skin reveals that thermally stable, flexible, and stretchable piezoelectric materials are required to be produced with high yields and in a cost-effective way for the fabrication of commercially feasible, large area, self-powering, and highly efficient devices. Nanowires have made great impacts on many disciplines including solar cells, biosensors and phase change memory devices. A similar impact is also expected on piezoelectric applications using PVDF nanowires. The prominent piezoelectric PVDF nanowire fabrication methods are anodized alumina (AAO) template molding, electrospinning and nanoimprint lithography (NI), which are all solvent dependent. Even though these techniques are appropriate to produce PVDF nanowires, they are not superior in all aspects considering the nanowire aspect ratio, uniformity, geometry control, yield, and device integrability in order to produce large area, low cost and high throughput devices. Despite the fact that high aspect ratio nanowires can be produced with high yield by using electrospinning, diameter uniformity and geometry control capability of this technique are not fulfilling the requirements of current state of the art technology. Tuning the diameter of nanowires can be better accomplished by using AAO and NI techniques. However, nanowires produced by these methods are not feasible to carry out the production of flexible, large area devices.

### SUMMARY OF THE INVENTION

This invention overcomes the shortages stated above by providing an iterative fiber drawing method for PVDF ribbon. The PVDF ribbon produced through the method has outstanding properties including spontaneous high piezoelectricity, high aspect ratio, excellent uniformity, desired geometry, and high yield.

The ribbon fabrication procedure starts with preparation of a multimaterial preform including a poly(ether sulfone) (PES) matrix and a PVDF slab contained in the PES matrix, then drawing a plurality of composite ribbons from the multimaterial preform at a temperature above glass transition temperature of PES matrix and melting point of PVDF slab, and extracting a plurality of PVDF ribbons out of the composite ribbons by a solvent.

This invention also provides a PVDF ribbon material produced with the method stated above. The thickness of the PVDF ribbon ranges from 5 nm to 1000 um. The γ phase percentage of the PVDF ribbon ranges from 72%-76%. The γ phase PVDF produced by the method stated in the present invention is stable at high temperature of 175° C. A large average effective piezoelectric coefficient with −58.5 pm/v is measured from a PVDF ribbon with a thick of 80 nm and wide of 180 nm.

In conclusion, the beneficial effect of the present invention is that providing a low cost method for making a PVDF ribbon with outstanding properties including spontaneous high piezoelectricity, high aspect ratio, excellent uniformity, desired geometry, and high yield.

### BRIEF DESCRIPTION OF THE DRAWINGS

FIG. 1a is a flow chart of a method for making piezoelectricity materials according to a first embodiment.

FIG. 1b is a process chart of the method for making piezoelectricity materials of FIG. 1a.

FIG. 2 is a process chart of a method for making a PVDF slab.

FIG. 3 is a process chart of a method for making a nultimaterial preform.

FIG. 4a is a photograph of a first composite ribbon.

FIG. 4b is a scanning electron microscope (SEM) image of a cross section of the first composite ribbon of FIG. 4a.

FIG. 5a is a flow chart of a method for making piezoelectricity materials according to a second embodiment.

FIG. 5b is a process chart of the method of making piezoelectricity materials of FIG. 5a.

FIG. 6a is a SEM image of across section of a second composite ribbon.

FIG. 6b is a SEM image of a lateral view of the second composite ribbon of FIG. 6a.

FIG. 7a is a flow chart of a method for making piezoelectricity materials according to a third embodiment.

FIG. 7b is a process chart of the method of making piezoelectricity materials of FIG. 7a.

FIG. 8a is a SEM image of a cross section of a third composite ribbon.

FIG. 8b is a SEM image of lateral of the third composite ribbon of FIG. 8a.

FIG. 9 is a SEM image of a PVDF ribbon obtained from the first embodiment.

FIG. 10 is a SEM image of a PVDF ribbon obtained from the second embodiment.

FIG. 11 is a SEM image of a PVDF ribbon obtained from the third embodiment.

FIG. 12 shows a structural view of molecular conformations of α, β, γ phases of PVDF ribbons.

FIG. 13 shows a XRD spectrum of PVDF slab extracted from a preform, and PVDF ribbons obtained from the first, second, third embodiments.

FIG. 14 shows ATR-FTIR peaks of the PVDF ribbons obtained from the first, second and third embodiments.

FIG. 15 shows XRD patterns of characteristic peaks of PVDF ribbons obtained from the second embodiment at different annealing temperatures.

FIG. 16 shows activation energy of transitions from α and β phase to γ phase.

FIG. 17 shows a hysteresis loop of a single PVDF ribbon with a thickness of 80 nm and a width of 180 nm.

FIG. 18 shows a Displacement-voltage hysteresis loop of the single PVDF ribbon in FIG. 17 taken by an AFM and piezoelectric evaluation system.

FIG. 19 shows a COMSOL multiphysics simulation of displacement induced via tip indentation.

FIG. 20 shows a process of a method for making a first device using PVDF ribbons of the first embodiment.

FIG. 21 shows a structural view of a second device using PVDF ribbons of the second embodiment.

FIG. 22 shows a circuit diagram of a piezoelectric device.

FIG. 23 shows the impedance measurement curves of the piezoelectric devices in FIG. 22.

FIG. 24 shows voltage and current measurement curves of the devices produced using P1(a-b) and P2(c-d).

FIG. 25 shows voltage and current output curves of the devices produced using P1(a-b) and P2(c-d) under quasi-periodic tapping forces.

FIG. 26 shows piezoelectric response of another device built by using non-piezoelectric amorphous As₂Se₃ nanowires (150 nm in diameter) produced by thermal fiber drawing technique.

### DETAIL DESCRIPTION OF THE INVENTION

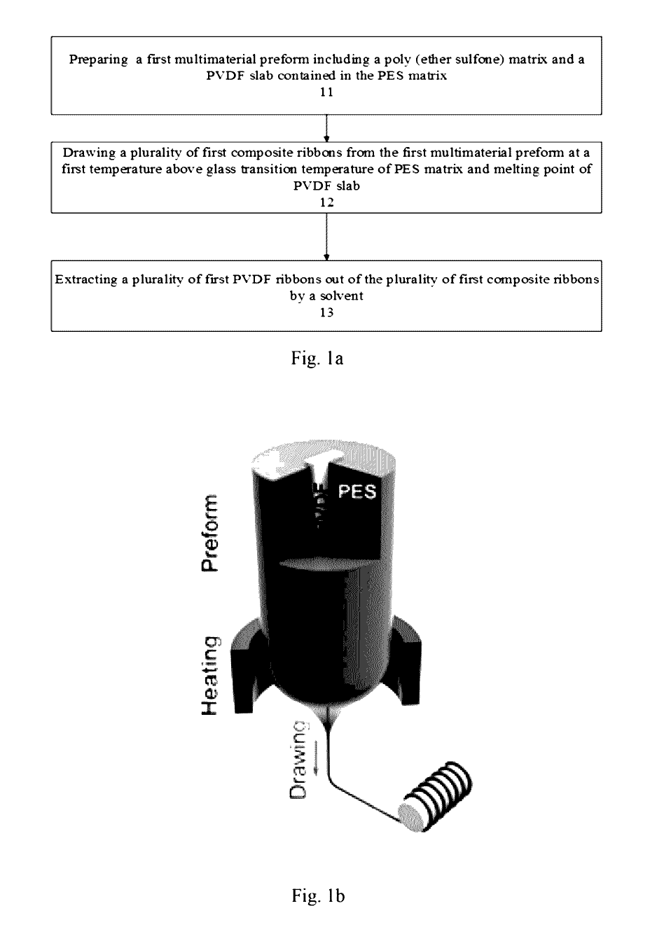

Referring to FIGS. 1a-1b, a method for making poly (vinylidene fluoride) (PVDF) ribbons with spontaneous high piezoelectricity, according to a first embodiment, includes the following steps:

S11, providing a first multimaterial preform including apoly(ether sulfone)(PES) matrix and a PVDF slab contained in the PES matrix;

S12, drawing a plurality of first composite ribbons from the first multimaterial preform at a first temperature above glass transition temperature of PES matrix and melting point of PVDF slab; and

S13, extracting a plurality of first PVDF ribbons out of the plurality of first composite ribbons by a solvent.

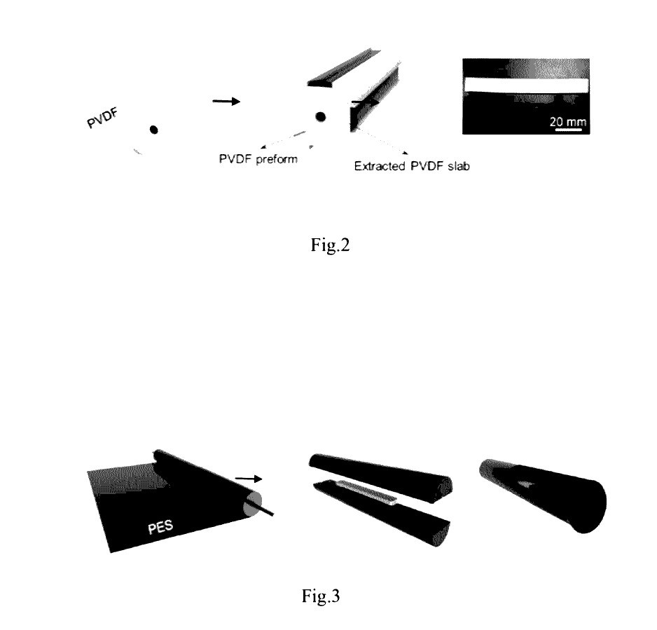

Referring to FIGS. 2-3, in step S11, the first multimaterial preform can be obtained by the following sub-steps:

S111: obtaining a PVDF slab and at least two PES slabs; and

S112: inserting the PVDF slab into the center of the at least two PES slabs to obtain the multimaterial preform.

In step S111, the PVDF slab can be obtained by the steps of:

S1111, rolling PVDF polymer films around a first substrate to form a first roll;

S1112, degassing the air trapped in the first roll under vacuum;

S1113, consolidating the first roll at a second temperature above a glass transition temperature of the PVDF polymer films to form a first consolidated roll under vacuum; and

S1114, cutting a PVDF slab from the first consolidated roll.

In step S1111, the thickness of the PVDF polymer films is not limited, and can be ranged from about 10 micrometers to about 100 micrometers. In one embodiment, the thickness of the PVDF polymer film is about 60 micrometers. The first substrate is used to support the PVDF polymer films and the shape of the first substrate is not limited. In one embodiment, the first substrate is a glass tube.

In step S1112, the degassing process is processed under a temperature below the glass transition temperature of the PVDF polymer films to prevent the air from being trapped in the first consolidated roll.

In step S1113, the first roll can be consolidated at a second temperature ranging from 165° C. to 200° C. for a certain period ranging from about 10 minutes to about 60 minutes under a vacuum degree below 10×10⁻² Torr. In one embodiment, the first roll is consolidated at a temperature of about 180° C. for about 30 minutes under a vacuum degree of about 2×10⁻² Torr. In this step, the PVDF polymer films can be consolidated to form a uniform integrated PVDF.

In step S1114, the PVDF slab can be cut by a knife from the first consolidated roll.

The at least two PES slabs can be obtained by the steps of:

S1111′, rolling PES films around a second substrate to form a second roll;

S1112′, degassing the air trapped in the second roll under vacuum;

S1113′, consolidating the second roll at a third temperature above glass transition temperature of the PES films to form a second consolidated roll under vacuum; and

S1114′, splitting the second consolidated roll in two halves and machining in the center to open a niche for inserting the PVDF slab.

In step S1111′, a thickness of the PES films is not limited, and can be ranged from about 50 micrometers to about 500 micrometers. In one embodiment, the thickness of the PES films is about 100 micrometers. The second substrate is used to support the PES films and the shape of second substrate is not limited. In one embodiment, the second substrate is a glass tube with a diameter of about 3 millimeters and a length of about 25 centimeters. A diameter and a length of the second roll is not limited, in one embodiment, the diameter of the second roll is about 35 millimeters, and a length of the second roll is about 25 centimeters.

In step S1112′, the degassing process is processed under a temperature below the glass transition temperature of the PES polymer films to prevent the air from trapped in the second consolidated roll.

In step S1113′, the second roll is consolidated at the third temperature ranging from about 220° C. to about 270° C. for a certain period ranging from 10 minutes to 60 minutes under a vacuum degree below 10×10⁻² Torr. In one embodiment, the second roll is consolidated at a temperature of about 255° C. for about 35 minutes under a vacuum degree of about 2×10⁻² Torr. In this step, PES films can be consolidated to form an integrated uniform PES roll.

In step S12, the plurality of first composite ribbons can be drawn at the first temperature ranging from about 250° C. to about 300° C. Furthermore, a tensile stress of drawing can be ranged from 1 MPa to 5 MPa to trigger plastic deformation of the first multi-material preform. A preform feeding speed of drawing can be ranged from 1 mm/sec to 20 mm/sec in order to form a continuous ribbon. In one embodiment, the plurality of the first composite ribbons are drawn by a tensile stress of about 3 MPa at a preform feeding speed of about 8 mm/sec under about 285° C.

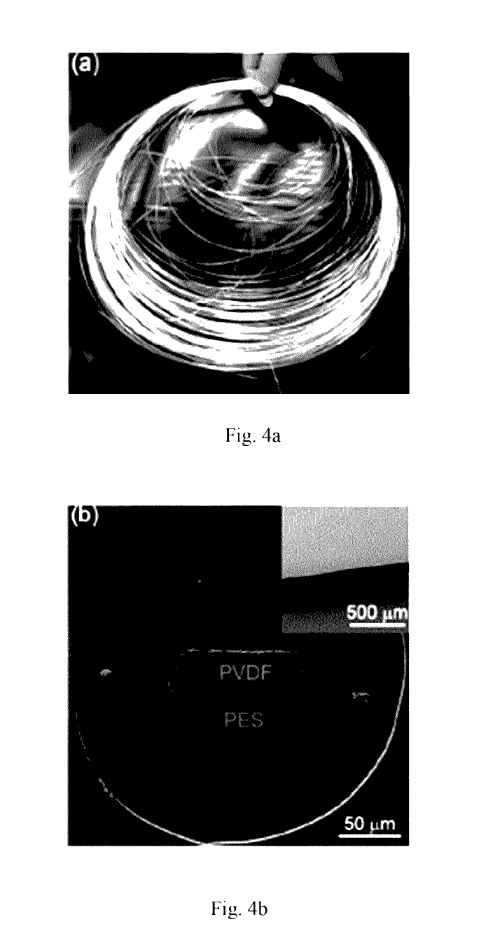

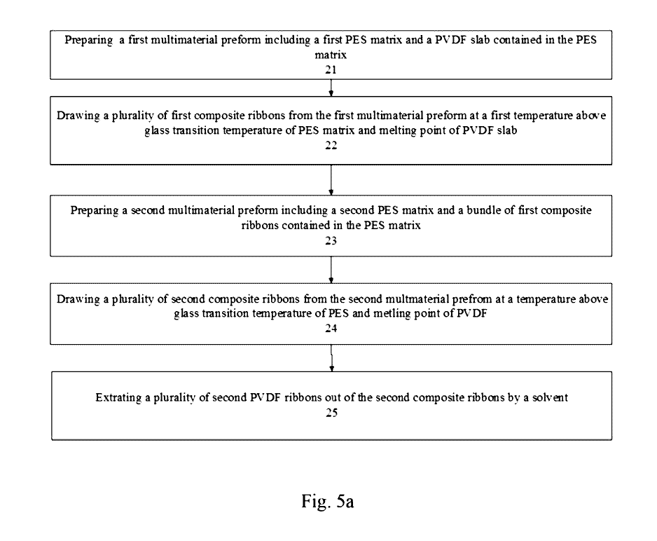

Referring to FIGS. 4a-4b, FIG. 4a-4b shows SEM images of the first composite ribbon obtained by the above method.

In step S13, the plurality of first PVDF ribbons can be extracted out of the first composite ribbons by immersing the plurality of first PVDF ribbons into the solvent. The solvent can be an organic solvent, which can dissolve PES without dissolving PDVF. In one embodiment, the plurality of first PVDF ribbons are extracted out of the first composite ribbons by dichloromethane (DCM).

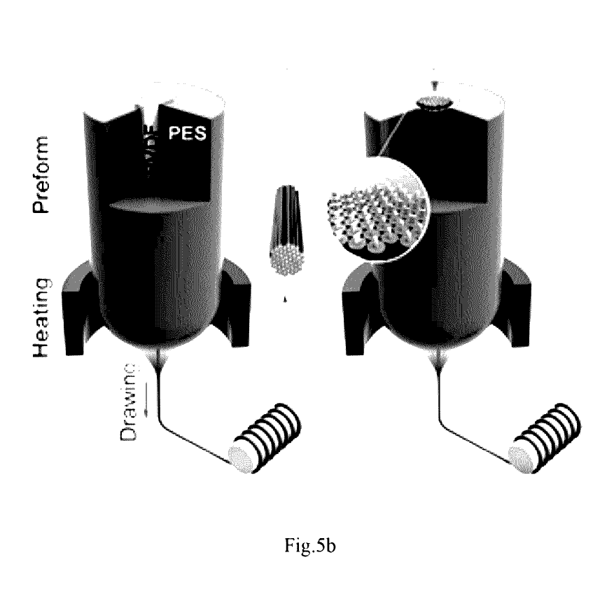

Referring to FIGS. 5a-5b, a method for making PVDF ribbons with spontaneous high piezoelectricity, according to a second embodiment, includes the following steps:

S21, preparing a first multi-material preform including a first PES matrix and a PVDF slab contained in the PES matrix;

S22, drawing a plurality of first composite ribbons from the first multi-material preform at a first temperature above glass transition temperature of PES matrix and melting point of PVDF slab;

S23, preparing a second multi-material preform including the PES matrix and a bundle of first composite ribbons contained in the PES matrix;

S24, drawing a plurality of second composite ribbons from the second multi-material preform at a temperature above glass transition temperature of PES and melting point of PVDF; and

S25, extracting a plurality of second PVDF ribbons out of the second composite ribbons by a solvent.

In step S21, the first multi-material preform can be obtained by the following sub-steps:

S211: obtaining a PVDF slab and at least two PES slabs; and

S212: inserting the PVDF slab into the center of at least two PES slabs to obtain the multi-material preform.

In step S211, the PVDF slab can be obtained by the steps of:

S2111, rolling PVDF polymer films around a first substrate to form a first roll,

s2112, degassing the air trapped in the first roll under vacuum;

S2113, consolidating the first roll at a second temperature above a glass transition temperature of the PVDF polymer films to form a first consolidated roll under vacuum; and

S2114, cutting a PVDF slab from the first consolidated roll.

In step S2111, a thickness of the PVDF polymer films is not limited, and can range from about 10 micrometers to about 100 micrometers. In one embodiment, the thickness of the PVDF polymer films is about 60 micrometers. The first substrate is used to support the PVDF polymer films and the shape of first substrate is not limited. In one embodiment, the first substrate is a glass tube.

In step S2112, the degassing process is processed under a temperature below the glass transition temperature of the PVDF polymer films to prevent the air from being trapped in the first consolidated roll.

In step S2113, the first roll can be consolidated at a second temperature ranging from 165° C. to 200° C. for a certain period ranging from about 10 minutes to about 60 minutes under a vacuum degree below 10×10⁻² Torr. In one embodiment, the first roll is consolidated at a temperature of about 180° C. for about 30 minutes under a vacuum degree of about 2×10⁻² Torr. In this step, the PVDF polymer films can be consolidated to form a uniform integrated PVDF roll.

In step S2114, the PVDF slab can be cut by a knife from the first consolidated roll.

The at least two PES slabs can be obtained by the steps of:

S2111′, rolling PES films around a second substrate to form a second roll;

S2112′, degassing the air trapped in the second roll under vacuum;

S2113′, consolidating the second roll at a third temperature above glass transition temperature of the PES films to form a second consolidated roil under vacuum; and

S2114′ splitting the second consolidated roll in two halves and machining in the center to open a niche for inserting the PVDF slab.

In step S2111′, a thickness of the PES films is not limited, and can be ranged from about 50 micrometers to about 500 micrometers. In one embodiment, the thickness of the PES films is about 100 micrometers. The second substrate is used to support the PES films and the shape of the second substrate is not limited. In one embodiment, the second substrate is a glass tube with a diameter of about 3 millimeters and a length of about 25 centimeters. A diameter and a length of the second roll is not limited, in one embodiment, the diameter of the second roll is about 35 millimeters, and a length of the second roll is about 25 centimeters.

In step S2113′, the second roll is consolidated at the third temperature ranging from about 2.20° C. to about 270° C. for a certain period ranging from 10 minutes to 60 minutes under a vacuum degree below 10×10⁻² Torr. In one embodiment, the second roll is consolidated at a temperature of about 255° C. for about 35 minutes under a vacuum degree of about 2×10⁻² Torr. In this step, PES films can be consolidated to form an integrated uniform PES roll.

In step S22, a plurality of first composite ribbons can be drawn at the first temperature ranged from about 250° C. to about 300° C. Furthermore, a tensile stress of drawing can range from 1 MPa to 5 MPa to trigger plastic deformation of the first multi-material preform. A preform feeding speed of drawing can be ranged from 1 mm/sec to 20 mm/sec in order to form continuous ribbons. In one embodiment, the plurality of first composite ribbons are drawn by a tensile stress of about 3 MPa at a preform feeding speed of about 8 mm/sec under about 285° C.

In step S23, the second multi-material preform can be formed by the following sub-steps:

S231, forming a bundle of the first composite ribbons; and

S232, inserting the bundle of the first composite ribbons into the PES matrix.

In step S231, the bundle of the first composite ribbons can be formed by stacking 1-1000 first composite ribbons together. In one embodiment, the bundle of first composite ribbons is formed by stacking 400 first composite ribbons together.

In step S232, the PES matrix can be obtained according to the first embodiment mentioned above.

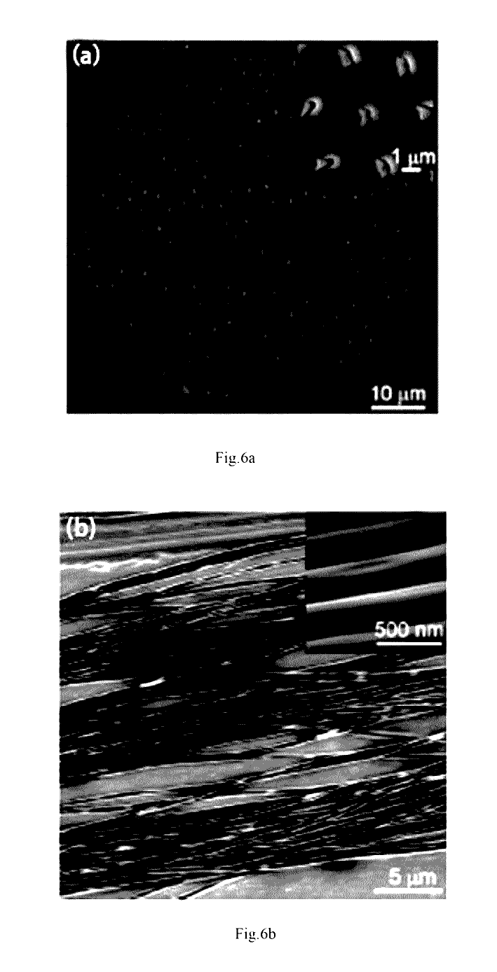

In step S24, the plurality of second composite ribbons can be drawn at the first temperature ranging from about 250° C. to about 300° C. Furthermore, a tensile stress of drawing can range from 1 MPa to 5 MPa to trigger plastic deformation of the second multi-material preform. A preform feeding speed of drawing can be ranged from 1 mm/sec to 20 mm/sec in order to form continuous ribbons. In one embodiment, the plurality of :first composite ribbons are drawn by a tensile stress of about 3 MPa at a preform feeding speed of about 8 mm/sec under about 285° C. Amended accordingly. Referring to FIG. 6a-6b, FIG. 6a-6b shows SEM images of the second composite ribbons obtained by the above method.

In step S25, the plurality of second PVDF ribbons can be extracted out of the second composite ribbons by immersing the plurality of second PVDF ribbons into the solvent. The solvent can be an organic solvent, which can dissolve PES without dissolving PVDF. In one embodiment, the plurality of second PVDF ribbons are extracted out of the second composite ribbons by dichloromethane (DCM).

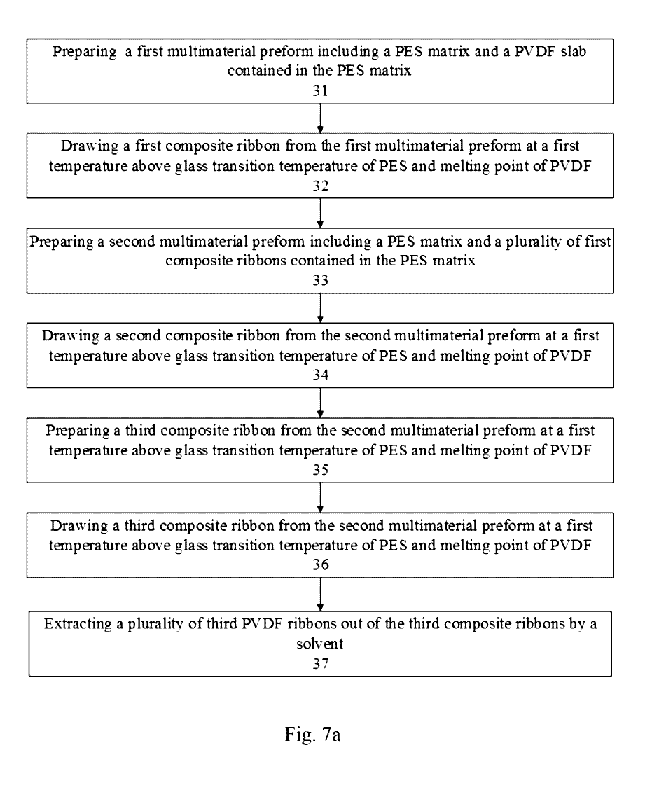

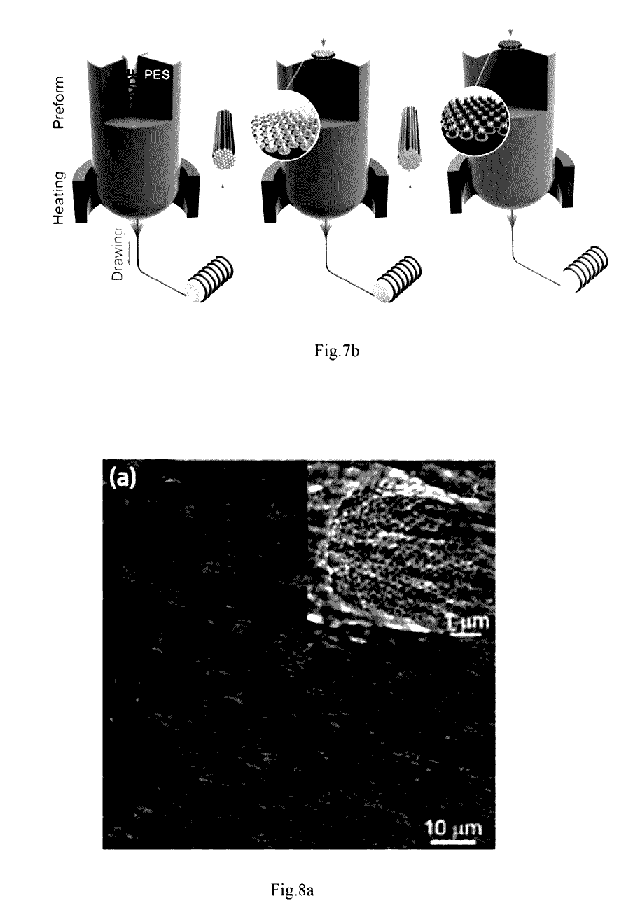

Referring to FIGS. 7a and 7b, a method for making PVDF ribbons with spontaneous high piezoelectricity; according to a third embodiment, includes the following steps:

S31, preparing a first multi-material preform including a PES matrix and a PVDF slab contained in the PES matrix;

S32, drawing a first composite ribbon from the first multi-material preform at a first temperature above glass transition temperature of PES and melting point of PVDF; and

S33, preparing a second multi-material preform including a PES matrix and a bundle of first composite ribbons contained in the PES matrix;

S34, drawing a second composite ribbon from the second multi-material preform at a temperature above glass transition temperature of PES and melting point of PVDF; and

S35, preparing a third multi-material preform including a PES matrix and a bundle of second composite ribbons contained in the PES matrix;

S36, drawing a third composite ribbon from the second multi-material preform at a temperature above glass transition temperature of PES and melting point of PVDF; and

S37, extracting a plurality of third PVDF ribbons out of the third composite ribbons by a solvent.

In step S31, the first multi-material preform can be obtained by the following sub-steps:

S311: obtaining a PVDF slab and at least two PES slabs; and

S312: inserting the PVDF slab into the center of the at least two PES slabs to obtain the multi-material preform.

In step S311, the PVDF slab can be obtained by the steps of:

S3111, rolling PVDF polymer films around a first substrate to form a first roll;

S3112, degassing the air trapped in the first roll under vacuum;

S3113, consolidating the first roll at a second temperature above a glass transition temperature of the PVDF polymer films to form a first consolidated roll under vacuum; and

S3114, cutting a PVDF slab from the first consolidated roll.

In step S3111, a thickness of the PVDF polymer films is not limited, and can range from about 10 micrometers to about 100 micrometers. In one embodiment, the thickness of the PVDF polymer films is about 60 micrometers. The first substrate is used to support the PVDF polymer films and the shape of first substrate is not limited. In one embodiment, the first substrate is a glass tube.

In step S3112, the degassing process is processed under a temperature below the glass transition temperature of the PVDF polymer films to prevent the air from being trapped in the first consolidated roll.

In step S3113, the first roll can be consolidated at a second temperature ranging from 165° C. to 200° C. for a certain period ranging from about 10 minutes to about 60 minutes under a vacuum degree below 10×10⁻² Torr. In one embodiment, the first roll is consolidated at a temperature of about 180° C. for about 30 minutes under a vacuum degree of about 2×10⁻² Torr. In this step, the PVDF polymer films can be consolidated to form a uniform integrated PVDF roll.

In step S3114, the PVDF slab can be cut by a knife from the first consolidated roll.

The at least two PES slabs can be obtained by the steps of:

S3111′, rolling PES films around a second substrate to form a second roll;

S3112′, degassing the air trapped in the second roll under vacuum;

S3113′, consolidating the second roll at a third temperature above glass transition temperature of the PES films to form a second consolidated roll under vacuum; and

S3114′, splitting the second consolidated roll in two halves and machining in the center to open a niche for inserting the PVDE slab.

In step S3111′, a thickness of the PES films is riot limited, and can range from about 50 micrometers to about 500 micrometers. In one embodiment, the thickness of the PES films is about 100 micrometers. The second substrate is used to support the PES films and the shape of the second substrate is not limited. In one embodiment, the second substrate is a glass tube with a diameter of about 3 millimeters and a length of about 25 centimeters. A diameter and a length of the second roll is not limited, in one embodiment, the diameter of the second roll is about 35 millimeters, and a length of the second roll is about 25 centimeters.

In step S3113′, the second roll is consolidated at the third temperature ranging from about 220° C. to about 270° C. for a certain period ranging from 10 minutes to 60 minutes under a vacuum degree below 10×10⁻² Torr. In one embodiment, the second roll is consolidated at a temperature of about 255° C. for about 35 minutes under a vacuum degree of about 2×10⁻² Torr. In this step, PES films can be consolidated to form an integrated uniform PES roll.

In step S32, a plurality of first composite ribbons can be drawn at the first temperature ranged from about 250° C. to about 300° C. Furthermore, a tensile stress of drawing can range from 1 MPa to 5 MPa to trigger plastic deformation of the first multi-material preform. A preform feeding speed of drawing can be ranged from 1 mm/sec to 20 mm/sec in order to form continuous ribbons. In one embodiment, the plurality of first composite ribbons are drew by a tensile stress of about 3 MPa at a preform feeding speed of about 8 mm/sec under about 285° C.

In step S33, the second multi-material preform can be formed by the following sub-steps:

S331, forming a bundle of the first composite ribbons; and

S332, inserting the bundle of the first composite ribbons into the PES matrix,

In step S331, the bundle of the first composite ribbons can be formed by stacking 1-1000 first composite ribbons together. In one embodiment, the bundle of the first composite ribbons is formed by stacking 400 first composite ribbons together.

In step S332, the PES matrix can be obtained according to the first embodiment mentioned above.

In step S34, a plurality of second composite ribbons can be drawn at the first temperature ranged from about 250° C. to about 300° C. Furthermore, a tensile Stress of drawing can be ranged from 1 MPa to 5 MPa to trigger plastic deformation of the first multi-material preform. A preform feeding speed of drawing can be ranged from 1 mm/sec to 20 mm/sec in order to form continuous ribbons. In one embodiment, the plurality of first composite ribbons are drawn by a tensile stress of about 3 MPa at a preform feeding speed of about 8 mm/sec under about 285° C.

In step S35, the third multi-material preform can be formed by the following sub-steps:

S351, forming a bundle of the second composite ribbons; and

S352, inserting the bundle of the second composite ribbons into the PES matrix.

In step S351, the bundle of the second composite ribbons can be formed by stacking 1-1000 second composite ribbons together. In one embodiment, the bundle of the second composite ribbons is made by stacking 400 second composite ribbons together.

In step S352, the PES matrix can be obtained according to the first embodiment mentioned above.

In step S36, the plurality of third composite ribbons can be drawn at the first temperature ranged from about 250° C. to about 300° C. Furthermore, a tensile stress of drawing can be ranged from 1 MPa to 5 MPa to trigger plastic deformation of the third multi-material preform. A preform feeding speed of drawing can be ranged from 1 mm/sec to 20 mm/sec in order to form continuous ribbons. In one embodiment, the plurality of third composite ribbons are drawn by a tensile stress of about 3 MPa at a preform feeding speed of about 8 mm/sec under about 285° C. Amended accordingly. Referring to FIGS. 8a-8b, FIGS. 8a-8b show SEM images of the third composite ribbons obtained by the above method.

In step S37, the plurality of second PVDF ribbons can be extracted out of the second composite ribbons by immersing the plurality of second PVDF ribbons into the solvent. The solvent can be an organic solvent, which can dissolve PES without dissolving PVDF. In one embodiment, the plurality of second PVDF ribbons are extracted out of the second composite ribbons by dichloromethane (DCM).

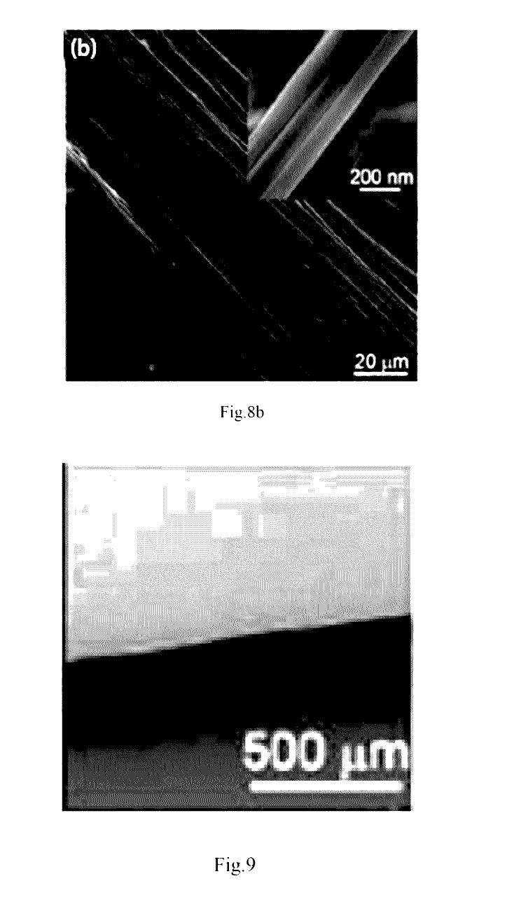

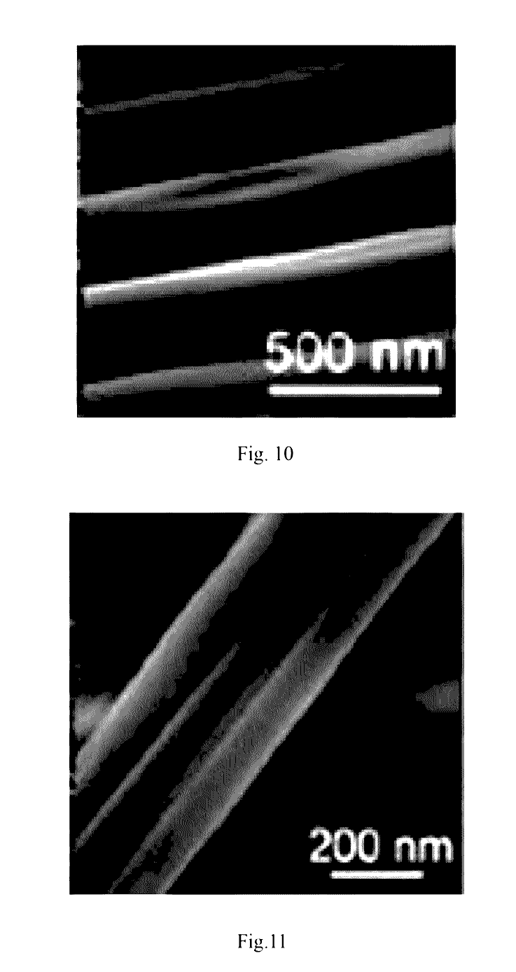

PVDF ribbons with spontaneous high piezoelectricity are obtained by the method stated above. The length of PVDF ribbons range from 10 m to 35000 km, the thickness of the PVDF ribbons range from 5 nm to 1000 um. Referring to FIGS. 9, 10 and 11, FIGS. 9, 10 and 11 show the SEM images of PVDF ribbons with spontaneous high piezoelectricity obtained by the first, second, and third embodiments stated above respectively, which are labeled as P1, P2 and P3. Also referring to table 1, table 1 shows lengths and thicknesses of the PVDF ribbons obtained by the first, second, and third embodiments stated above.

TABLE 1

| | P1 | | P2 | | P3 | |
|---|---|---|---|---|---|---|
| Thickness | 1-1000 | um | 50-1000 | nm | 5-50 | nm |
| Total length | 10-3000 | m | 10-300 | km | 30000-35000 | km |

As showed in table 1, in the first embodiment, a thickness of the PVDF ribbons with spontaneous high piezoelectricity ranges from 1-1000 um, and a length of the PVDF ribbons with spontaneous high piezoelectricity ranges from 10 to 3000 m; in the second embodiment, a thickness of the PVDF ribbons with spontaneous high piezoelectricity ranges from 50-1000 nm, and a length of the PVDF ribbons with spontaneous high piezoelectricity ranges from 10 to 300 km; in the third embodiment, a thickness of the PVDF ribbons with spontaneous high piezoelectricity ranged from 5-50 nm, and a length of the PVDF ribbons with spontaneous high piezoelectricity ranges from 30000 km to 35000 km.

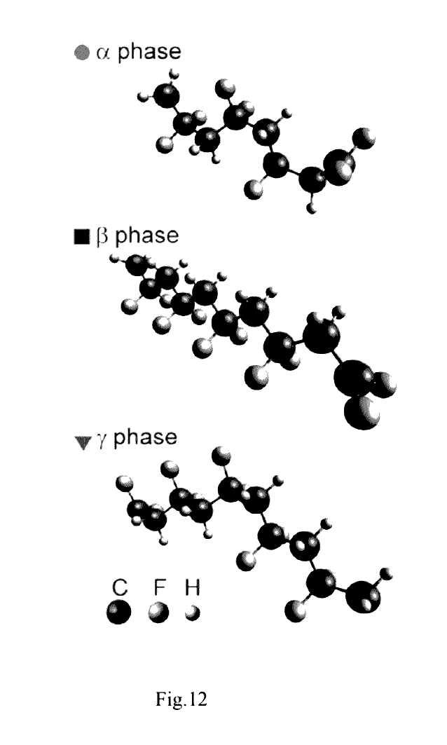

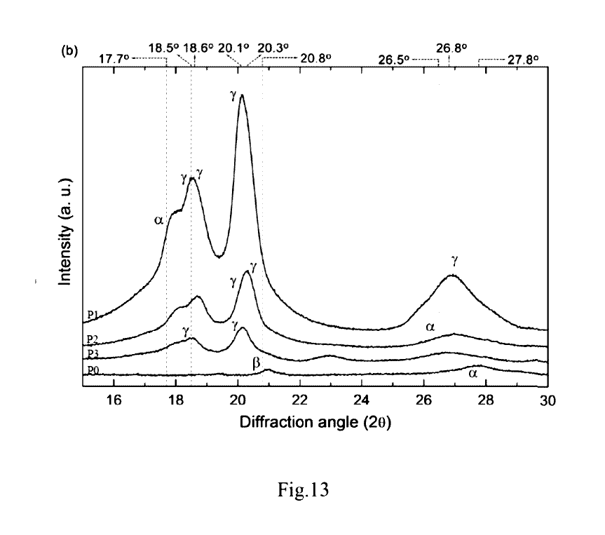

The molecular conformation of α, β, γ phases of PVDF ribbons are shown in FIG. 12. In the literature characteristic peak positions (2θ) of PVDF are tabulated as 17.7°, 18.4°, 19.9°, 26.5°, 27.8°, 35.7°, 39° and 57.4° for α phase; 20°, 20.8°, 35°, 36.6° and 56.1° for β phase; 18.5°, 19.2°, 20.1°, 20.3°, 26.8°, 36.2°, and 38.7° for γ phase. FIG. 13 shows the difference of phase content in different embodiments. The curve of the PVDF slab is labeled as P0. The curve of P0 shows that the PVDF slab includes a minor amount of β (2θ=20.7°) and α (2θ=27.8°) phases. The curve of P1 shows that a transition trend to the γ phase is persistent starting from the PVDF ribbons in the first embodiment. Although in the first embodiment, suppressed α phase peaks still exist at 17.7°, 26.5° and 27.8° peak positions, dominance of the γ phase is obvious from the peaks at 2θ=18.5°, 20.1° and 26.8°. The curve of P2 shows that except shifts observed in γ peak positions from 20.1° to 20.3°, and 18.5° to 18.6°, other peaks preserve their positions. The curve of P3 shows that characteristic peaks of γ phase are located at the same peak positions of P1. Broadening in the γ phase peaks and drastic fall in 2θ=26.8° peak intensity indicate a slight decrease in amount of γ phase of P2 and P3.

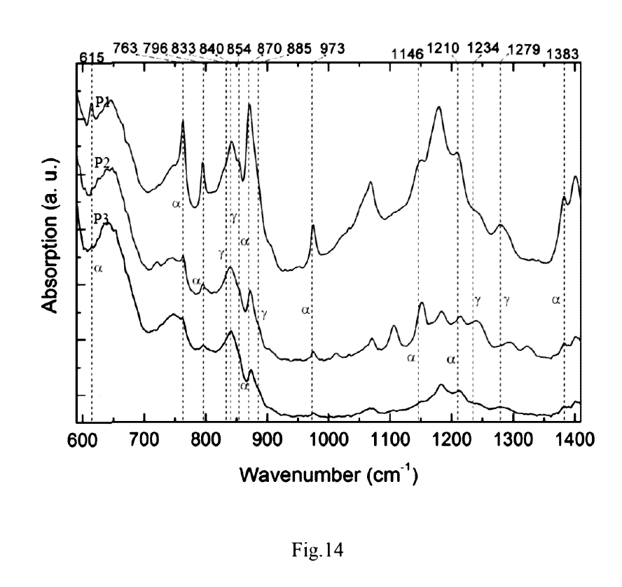

In FIG. 14, ATR-FTIR is also used for analyzing and confirming the phase distribution in the PVDF ribbons. Absorption band characteristics of α, β, and γ phases of PVDF are identified as given in literature: 532, 612, 763, 796, 854, 870, 974, 1146, 1210, 1383 and 1423 cm⁻¹ for α: 510, 840, 1279, 1286 and 1431 cm⁻¹ for β: 812, 833, 838, 885 and 1234 cm⁻¹ bands for γ. However, most of the absorption bands are superimposed for β and γ phases hindering the phase discrimination. Overlapping peaks at 840, 1279, and 1286 cm⁻¹ with γ and β phases can be assigned for γ phase as long as no β peak is identified using the XRD technique for ribbons. FIG. 14 represents ATR-FTIR absorption spectra for PVDF ribbons produced in the embodiments. Fraction of the γ phase is calculated using the following equation (1):

$$F ( γ ) = \frac{{X}_{γ}}{{X}_{α} + {X}_{γ}} \times 100 = \frac{{A}_{γ}}{( {K}_{γ} / {K}_{α} ) {A}_{α} + {A}_{γ}} \times 100 \qquad ( 1 )$$

where the Xγ and Xα are degrees of crystallinity, Aγ and Aα are measured absorbance intensity, Kγ and Kα are wavelength dependent absorption coefficients and F(γ) is the percentage of γ phase. γ percentage is calculated for 763 cm⁻¹ α peak and 833 cm⁻¹γ peak using corresponding absorbance coefficients Kγ=0.150 μm⁻¹ α peak and Kα=0.365 μm⁻¹ (Beer—Lambert Law), respectively. γ phase percentage of P1 is 76%, whereas P2 and P3, γ phase percentage decreased to 72% as a result of diminishing shear force on ribbons exposed to heat retreatment with smaller cross sectional areas.

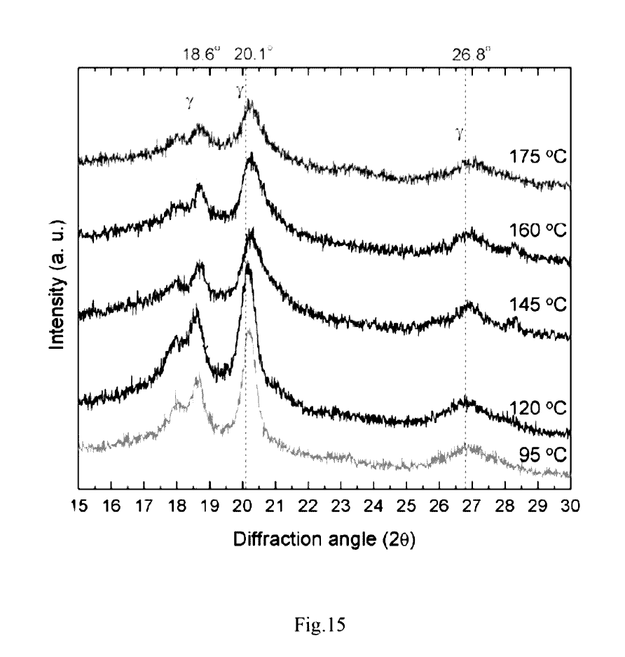

Because the phase transformation into γ phase occurs at high temperatures, stability of the γ phase at harsh conditions needs to be investigated. γ phase PVDF produced by iterative fiber drawing technique is quitestable at high temperatures. FIG. 15 shows the XRD of PVDF ribbons extracted out of the PES cladding annealed at several different temperatures. It is evident from XRD peaks that there is no significant change in γ phase content. It is clearly observed from the peaks at 2θ=18.6°, 20.1° and 26.8°, γ phase still exists at elevated temperature. Regarding broadening and decreasing intensity of XRD peaks, we observed that crystallinity is slightly diminished due to effect of high temperature.

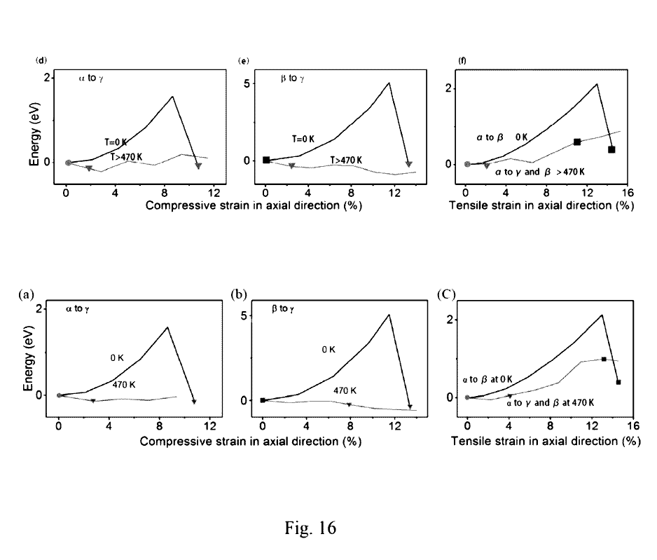

Structural changes due to temperature and induced stress during the fiber drawing are investigated by ab initio calculations. FIG. 16 shows a phase transition trend from α and β forms to γ form under tensile and compressive strain. The temperature in the simulation is set to 470 K, which corresponds to PVDF core temperature during drawing process and which also is well above the melting temperature of PVDF. For comparison and to understand the effect of temperature, the calculations are also performed at 0 K (which actually corresponds to the case where temperature effects are excluded in ab initio simulations to obtain ground state properties). The applied force in the fiber drawing axis causes stretching in the same direction but compression in the perpendicular directions. As the orientation of the molecules with respect to fiber drawing axis in the bulk PVDF can vary, all strain components that occurred during the fiber drawing should be taken into account in the ab initio model in which we considered tensile and compressive strains in the system as lattice stretching and lattice compression, respectively. The results are summarized in FIG. 16a-c, where circle, square and triangle represent the molecular chains in FIG. 12. When a compressive strain is applied in axial direction of α and β form PVDF, a transformation from α to imperfect γ phase with longer nonpolar parts, and a transformation from β to ideal γ phase are clearly observed at both 0 and 470 K. Although a very high activation energy of 1.6 and 5.1 eV, which practically makes the transformation impossible, is required at 0 K for the transition from α and β to γ phase, respectively, the same phase change phenomena occur with almost no energy barrier at 470 K. The required strain for phase transformation is significantly reduced with temperature as well. While transformations from α to γ occurs at 10.8% and β to γ at 13.4% compressive strain at 0 K. the same transformations are observed at 3 and 8% at 470 K. The similar trends are observed at higher temperatures with a small amount reduction in the required strain (FIG. 16d-f). These results indicate that the temperature above the melting point of PVDF during the fiber drawing process enables the phase transformation from other phases to γ phase by decreasing the required compressive strain and energy barrier. The peaks obtained at 2θ=17.7°, 26.5° and 27.820 from XRD data, which correspond to a phase PVDF as shown in FIG. 12, can be explained by imperfect transformation from α to γ phase. In a similar manner, tensile strain in axial direction is also applied. A direct phase transition from R to β phase is favored at 0 K when strain exceeds 14.6%, and the required activation energy is 2.1 eV. Interestingly, when the temperature is elevated up to 470 K or more, instead of direct transition from α to β phase, γ phase appears in the first place at 2.2% transforming into a perfect γ phase at 4.4% of tensile strain with an energy barrier of 0.07 eV. If strain is further increased and reaches 13.1%, imperfect β phase can be obtained with an energy barrier of 1.0 eV (the imperfection of the β phase can be due to the requirement of the polarization process for the transformation). Therefore, simulation results show that energy barrier for α to γ transition (0.07 eV, triangle in FIG. 16c) under tension is lower than α to β transition (1 eV, square in FIG. 6c) under tension.

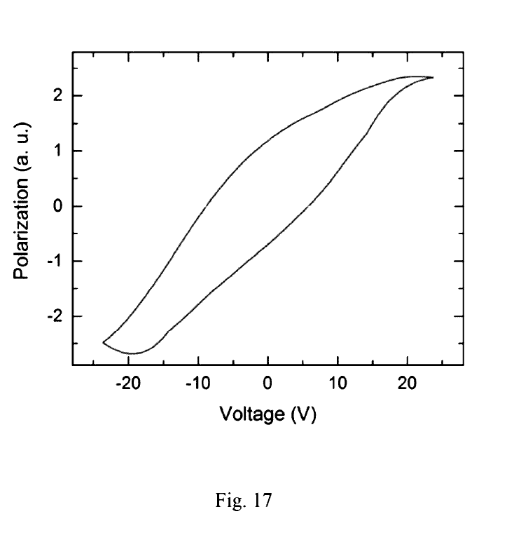

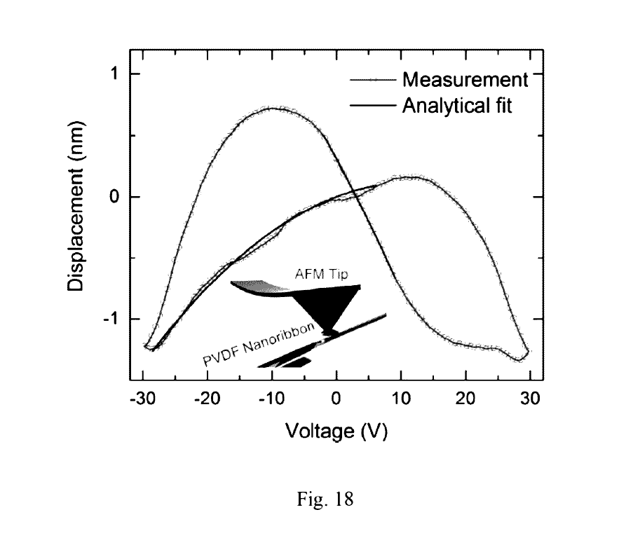

Electrical characterizations such as piezoelectric displacement and ferroelectric hysteresis curve measurements are performed for PVDF ribbons produced through the methods stated above. Utilizing a (Radiant Premier II) piezoelectric evaluation system along with an AFM instrument simultaneously functioning as a high precision displacement sensor and a tool for electrical coupling to nanoscale surfaces, a large average effective piezoelectric coefficient (d₃₃=−58.5 pm/V) is measured from 80 nm thick, 180 nm wide single PVDF ribbons isolated from an as-produced bundle. FIG. 17 shows a ferroelectric hysteresis curve (polarization vs voltage) in arbitrary polarization units. Since PVDF is a multiferroic material and piezoresponse characterization of nanoscale piezoelectric materials is challenging, characterization of PVDF ribbons is inherently a multi-physical problem that requires consideration of internal and external variables such as local temperature changes, electrostriction, pyroelectricity ferroelasticity, electrostatic effects, indentation regime, applied electrical potential, contact (AFM Tip) sliding and drifting elects. Piezoelectric coefficient measurements using AFM and a piezoelectric evaluation system virtual ground mode) can be well understood in three sequential stages: sample, preparation, and mechanical contact with AFM tip, recording piezoelectric response, analyzing the acquired signals for calculating pure piezoelectric displacement. The ribbon structure provides convenience for piezoelectric measurements with AFM since a more conformal contact between the bottom of the ribbon and the conductive surface of the substrate diminishes the sliding and drifting adversities during measurements. Before local piezoelectric characterization, a noncontact mode AFM surface imaging is operated for locating a PVDF single ribbon among dispersed ribbons on a 60 nm silver coated silicon wafer. After a mechanical contact between AFM tip and the surface of the ribbon is accomplished in contact mode AFM, a displacement-voltage (D-V) measurement is conducted by applying 10 ms bipolar triangular voltage pulses between the AFM tip (electrical potential) and the metal coating of the substrate (ground). During piezoelectric measurements, we kept the AFM control loop off and recorded piezoelectric displacements in a very short time scale compared to that of AFM tip drift. In addition, multiple deflection measurements are used from each local contact surface. FIG. 18 shows an average D-V curve in order to analytically cancel drifting effects and calculate a more accurate piezoelectric coefficient. AFM is one of the most precise deflection sensors that can dynamically detect the change in the thickness of PVDF ribbons according to alternating electric potential. However, many artifacts can occur related to the applied electric field and contact indentation regime during piezoelectric measurements at nanoscales. Experimental and analytical approaches are used in order to eliminate such effects and analyze the origin of the large displacement in PVDF ribbons. First, electrostatic forces can dislocate AFM tip in nanoscale distances. This effect can be simply eliminated using a stiffer (k=40 N/m and f=300 kHz) AFM tip. Measured signal from AFM deflection corresponds to the change in the thickness of PVDF ribbon because, in principle, AFM tip follows the surface motions of the sample. From the mechanics of materials perspective, we can calculate the total strain (s=Δt/t) in PVDF ribbons, where t is the thickness of the ribbons and At is the measured change in thickness. The measured strain is not a pure piezoelectric deflection, but rather a sum of strain components caused by electrostriction, thermal effects and applied pressure in the direction of the electric field.

s=s_{piezoelectric}+s_{electrostriction}+sₜₕₑᵣₘₐₗ+sₚᵣₑₛₛᵤᵣₑ (2)

s=d₃₃E−QE²+λΔT+e₃₃σ₃₃ (3)

Where d₃₃ is the piezoelectric coefficient, E is the electric field, Q is the electrostriction coefficient, λ is the thermal expansion coefficient, ΔT is the change in the temperature, e₃₃ is the elastic coefficient and σ₃₃ is the stress. The pressure induced strain related to indentation regime or AFM tip can trigger ferroelastic motions in PVDF ribbons, unless the indentation force is very small and constant. It is needed to apply a voltage to the conductive tip, so it is required to make a mechanical contact with the surface of the ribbons. FIG. 18 shows a COMSOL multi-physics simulation. Which is designed to analyze the deformation of contact region during piezoelectric measurements. The simulation results show that applying a −60 nN indentation three on the 80 nm thick PVDF ribbon, which corresponds to 15 nm static deflection in AFM cantilever, triggers maximum 0.3 nm elastic deformation on the surface with an AFM tip diameter of 10 nm. Therefore, AFM tip is guaranteed to be in constant mechanical contact with the ribbon surface during measurements, due to the fact that the AFM tip deflection range is higher than the total piezoelectric displacement measured. Dilatation of PVDF ribbons and pyroelectric effects can also be ignored, because all measurements are conducted at constant room temperature. In addition, the change in the PVDF ribbon temperature as a function of the electric potential is modeled to consider the local temperature changes caused by joule heating, Joule heating is proportional to i² and R, where i is the traveling current across the PVDF thickness and R is the resistance. Since resulting current is very small, there is no change in the temperature caused by joule heating. Experimentally eliminating the pressure and temperature dependent strain components results in eq 4.

s=d₃₃E−QE² (4)

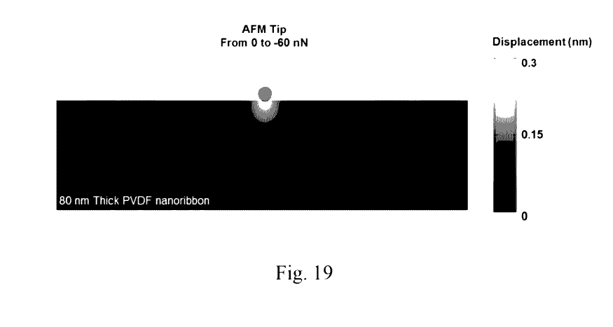

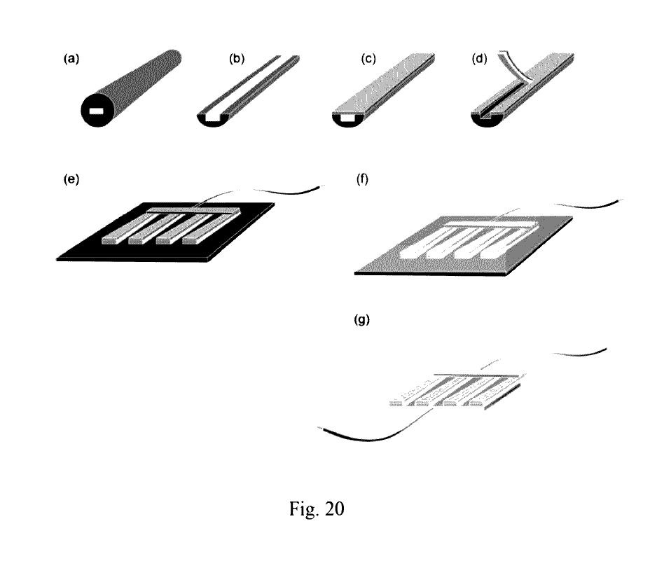

Inserting the measured data (displacement vs applied field) in eq 4, an overdetermined system of equations for two unknowns (d₃₃ and Q) is obtained, which can be solved in least-squares sense. Results are perfectly fitted to the measured curve as showed in FIG. 19. The electrostriction and piezoelectric coefficient of γ phase PVDF ribbons are calculated that, Q=−67.8×10⁻⁹ pm²/V² and d₃₃=−58.5 pm/V. In the range of a maximum ±10 V applied electric potential difference, 87.4% (585.3 pm) and 12.6% (84.47 pm) of the deflection result from pure piezoelectric effect and electrostriction, respectively. The measured average effective piezoelectric coefficient of γ phase PVDF ribbons is higher than the reported values of β phase (d₃₃=−30 pm/V) and γ phase (d₃₃=−7 pm/V) PVDF thin films, and on the same order of magnitude with β phase (d₃₃=−57.6 pm/V) PVDF nanowires, which are characterized in a similar manner using AFM. Unlike the ribbons, the effective d₃₃ coefficient for thin films is expected to be reduced, due to surface damping boundary conditions. The reverse form of D-V hysteresis loop (Butterfly Loop) is due to the negative value of d₃₃ coefficient. The general relation between piezoelectric coefficients of PVDF is d₃₃≧d₃₁>d₃₂>0. In order to confirm the measurement technique, the same measurement is conducted on a phase commercial PVDF thin film with 60 μm thickness, 25 μm² surface area, and no significant deflection is observed as expected.

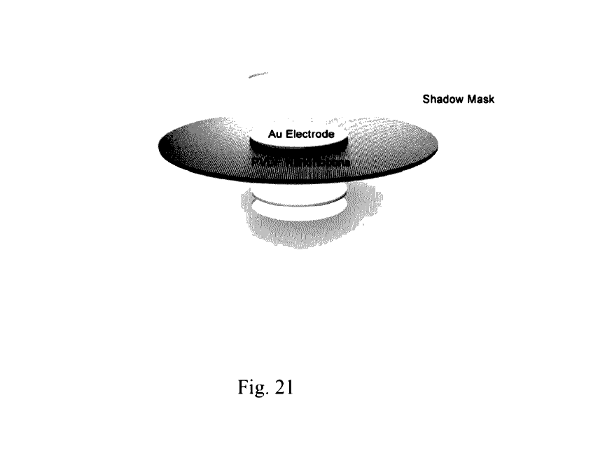

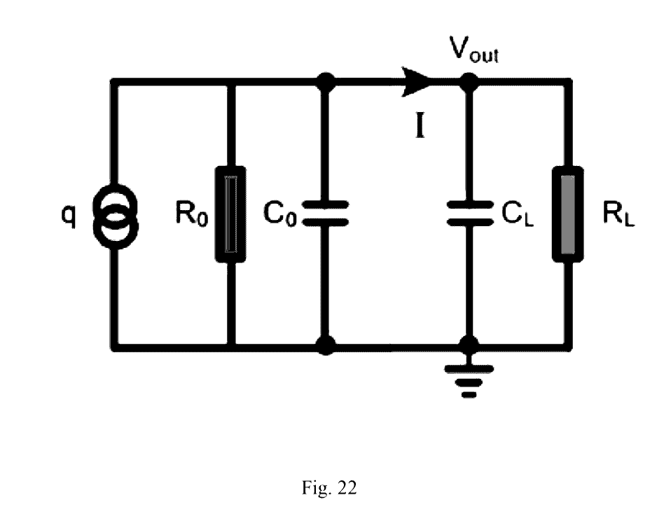

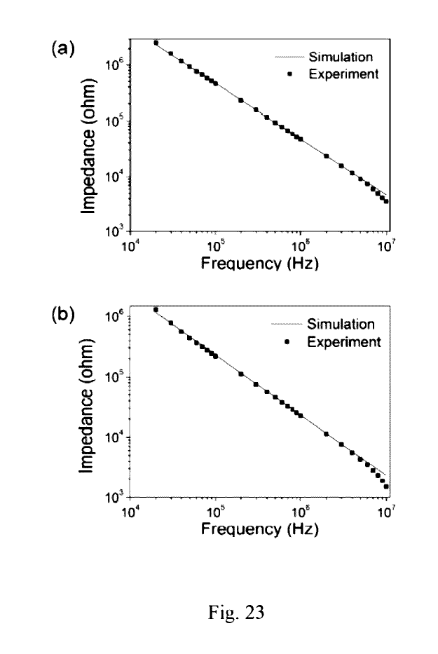

Two devices with different geometries are developed by using PVDF ribbons produced by the methods stated above. FIG. 20 shows the fabrication process for the first device, a fiber in the first embodiment is longitudinally divided in two halves without damaging the P1 PVDF ribbon and one face of the P1 PVDF ribbon is uncovered, 50 nm gold is sputtered on the open surface of the P1 ribbon. After mechanically removing the remaining part of PES cladding, the P1 ribbon is cut in smaller pieces and aligned on a silicon substrate, so that the gold deposited faces are on the top. A contact pad is attached to the gold-coated surface of 50 μm thick PVDF ribbons, and the structure is transferred onto a polydimethylsiloxane (PDMS) layer, which avoids the short circuit of the device and maintains the alignment of the P1 ribbons. Subsequently, the other surfaces of the P1 ribbons are also coated with 50 nm thick gold, and the whole device is embedded in PDMS (FIG. 20a-g). FIG. 21 shows the design of the second device using P2 PVDF ribbons produced by the method in the second embodiment. The second device with a different structure convenient for ribbons in nanoscale is fabricated using 300 nm PVDF ribbons produced by the method in the second embodiment. The P2 ribbons are extracted out of the PES cladding using DCM. The both side of the P2 ribbon bundles are coated with sputtering of 50 nm gold film using a shadow mask (FIG. 21). Misalignment of P2 ribbons is expected to be reduced output voltage and current of the device. Effective area of the devices fabricated using P1 ribbons and P2 ribbons are 100 mm² and 20 mm², respectively. Characterizations of the devices are carried out with an external load capacitance (CL=16 pF) and resistance (RL=10 mΩ). FIG. 22 shows an equivalent circuit for piezoelectric devices can be represented by a parallel RC circuit containing a charge source (q), a resistor (R₀), capacitor (C₀). FIG. 23 shows DC and impedance measurements of the devices. Internal resistor (R₀) and capacitor (C₀) for the first and second device are calculated to be R₀=100 GΩ and C₀=3.4 pF, R₀=40 GΩ and Cₒ=4.6 pF, respectively.

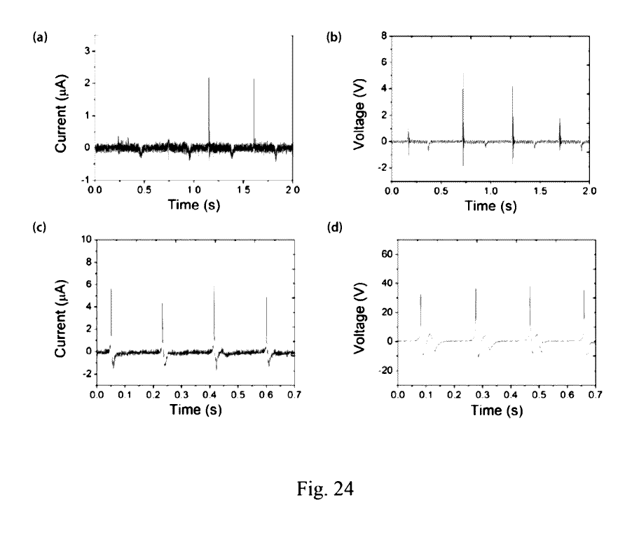

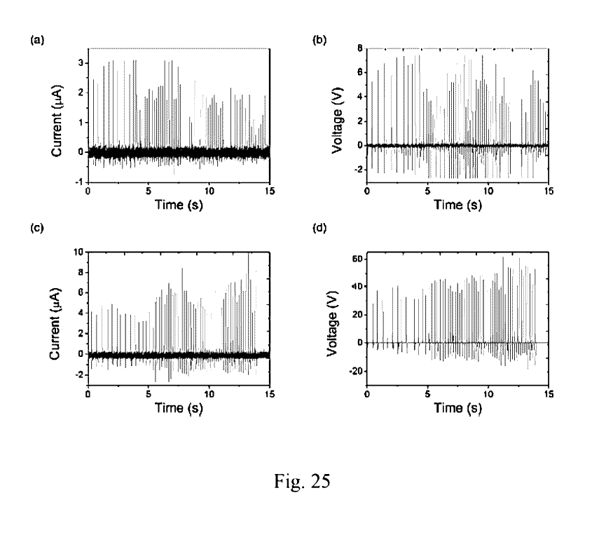

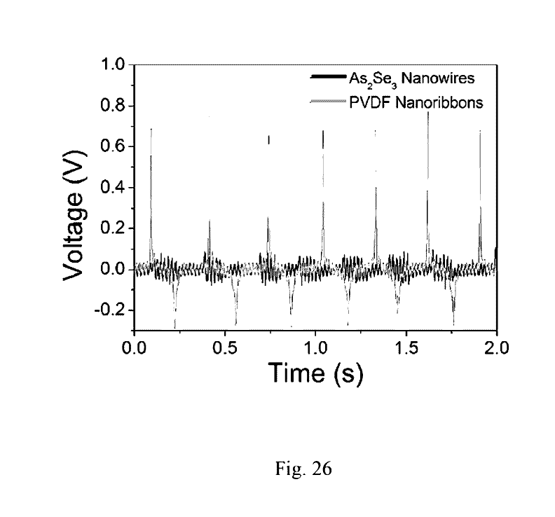

PVDF dipoles are oriented perpendicular to the fiber axis, when a force is applied vertical to the fiber axis, a positive piezoelectric potential is produce and collected on positive electrode. The same phenomenon occurs vice versa during the releasing. Output voltages and currents of the devices are recorded under quasi-periodic tapping forces. The output voltage and current are related to the magnitude and period of tapping force. FIG. 24 shows electrical characterization of the piezoelectric devices. The typical output values of the device fabricated using P1 ribbons with thickness of 50 um is 6 V and 3 μA (FIG. 24a-b), and the typical output values of the device produced using P2 ribbons with thickness of 300 nm is 40 V and 6 μA (FIG. 24c-d). Although P1 ribbons have 4% higher amount of polar phase content, charge collected from the device built with P2 ribbons is approximately 9 fold higher due to greater contact surface area (2 orders of magnitude higher) and better charge collection efficiency of ribbons. Maximum output (60 V and 10 μA for the P2 ribbons, 7 V and 3 μA for the P1 ribbons) of the piezoelectric devices can be seen from a broader range of the electrical measurements given in FIG. 25. Besides, peak output power densities of first and second devices are 5.25 and 750 μW/cm². FIG. 26 shows piezoelectric response of another device which is built by using nonpiezoelectric amorphous As₂Se₃ nanowires (150 nm in diameter) produced by thermal fiber drawing technique in order to confirm piezoelectric effect observed in our devices. There is no response observed except noise from the nonpiezoelectric device, despite the device produced using PVDF ribbons can response even for small tapping forces

The above embodiments are the descriptions of this invention. This invention should cover all equivalent modifications and combinations of these embodiments, and is not limited to these embodiments.

1. A method for making piezoelectricity material with spontaneous high piezoelectricity, comprising steps of:
preparing a first multi-material preform including a poly (ether sulfone) (PES) matrix and a PVDF slab contained in the PES matrix;
drawing a plurality of first composite ribbons from the first multi-material preform at a first temperature above glass transition temperature of PES matrix and melting point of PVDF slab; and
extracting a plurality of PVDF ribbons out of the composite ribbons by a solvent.

2. The method of claim 1, further comprising:
preparing a second multi-material preform including the PES matrix and a bundle of first composite ribbons contained in the PES matrix; and
drawing a plurality of second composite ribbons from the second multi-material preform at a temperature above glass transition temperature of PES and melting point of PVDF.

3. The method of claim 2, further comprising:
preparing a third multi-material preform including the PES matrix and a bundle of second composite ribbons contained in the PES matrix; and
drawing a plurality of third composite ribbon from the second multi-material preform at a temperature above glass transition temperature of PES and melting point of PVDF.

4. The method of claim 1, wherein the step of preparing the first multi-material preform comprises sub-steps of:
obtaining a PVDF slab and at least two PES slabs; and
inserting the PVDF slab into the center of the at least two PES slabs to obtain the multi-material preform.

5. The method of claim 4, wherein the step of obtaining the PVDF slab comprises sub-steps of:
rolling a plurality of PVDF polymer films around a first substrate to form a first roll;
degassing the air trapped in the first roll under vacuum;
consolidating the first roll at a second temperature above a glass transition temperature of the PVDF polymer films to form a first consolidated roll under vacuum; and
cutting the PVDF slab from the first consolidated roll.

6. The method of claim 5, wherein a thickness of the plurality of PVDF polymer films ranges from 10 um to 100 um.

7. The method of claim 5, wherein the degassing process is processed under a temperature below the glass transition temperature of the PVDF polymer films.

8. The method of claim 5, wherein the first roll is consolidated at the second temperature ranging from 165° C. to 200° C. for a period ranging from 10 minutes to 60 minutes under a vacuum degree below 10×10⁻² Torr.

9. The method of claim 4, wherein the step of obtaining the at least two PES slabs comprises sub-steps of:
rolling a plurality of PES polymer films around a second substrate to form a second roll;
degassing the air trapped in the second roll under vacuum;
consolidating the second roll at a temperature above glass transition temperature of the PES films to form a second consolidated roll under vacuum; and
splitting the second consolidated roll in two halves and machining in the center to open a niche for inserting the PVDF slab.

10. The method of claim 9, wherein a thickness of the plurality of PES films ranges from 50 um to 500 um.

11. The method of claim 9, wherein the second substrate is a glass tube.

12. The method of claim 9, wherein the degassing process is processed wider a temperature below the glass transition temperature of the PES polymer film.

13. The method of claim 9, wherein the second roll is consolidated at the third temperature ranged from 220° C. to 270° C. for a period ranged from 10 minutes to 60 minutes under a vacuum degree below 10×10⁻² Torr.

14. The method of claim 1, wherein the plurality of first composite ribbons is drawn by a tensile Stress ranged from 1 MPa to 5 MPa, with a preform feeding speed of ranged from 1 mm/sec to 20 mm/sec, at a temperature ranged from 250° C. to 300° C.

15. The method of claim 22, wherein the plurality of first composite ribbons is drawn at the first temperature of 285° C., the tensile stress of drawing is 3 MPa, a preform feeding speed of drawing is 8 mm/sec.

16. The method of claim 2, the step of preparing the second multi-material preform comprises sub-steps of:
forming a bundle of the first composite ribbons; and
inserting the bundle of the first composite ribbons into the PES matrix.

17. The method of claim 16, wherein the bundle of the first composite ribbons is formed by stacking 1-1000 first composite ribbons together.

18. The method of claim 2, wherein the plurality of second composite ribbons are drawn at the first temperature ranged from 250° C. to 300° C. a tensile stress of drawing ranges from 1 MPa to 5 MPa, a preform feeding speed of drawing ranges from 1 mm/sec to 20 mm/sec.

19. The method of claim 3, the step of preparing the third multi-material preform comprises sub-steps of:
forming a bundle of the second composite ribbons;
inserting the bundle of the second composite ribbons into the PES matrix.

20. The method of claim 19, wherein the bundle of the second composite ribbons is formed by stacking 1-1000 second composite ribbons together.

21. The method of claim 3, wherein the plurality of third composite ribbons is drawn by a tensile stress ranged from 1 MPa to 5 MPa, with a preform feeding speed of ranged from 1 mm/sec to 20 mm/sec, at a temperature ranged from 250° C. to 300° C.

22. The method of claim 1, wherein the solvent is an organic solvent capable of dissolving PES without dissolving PVDF.

23. The method of claim 22, wherein the solvent is dichloromethane (DCM).

24. A piezoelectricity material with spontaneous high piezoelectricity, comprising at least one PVDF ribbon, wherein a thickness of the at least one PVDF ribbon ranges from 5 nm to 1000 um.

25. The piezoelectricity material of claim 24, wherein a γ phase percentage of the PVDF ribbon material ranges from 72% to 76%.

26. The piezoelectricity material of claim 24, wherein the thickness of the at least one PVDF ribbon ranges from 50 nm to 1000 nm.

27. The piezoelectricity material of claim 26, wherein the thickness of the at least one the PVDF ribbon is 80 nm.

28. The piezoelectricity material of claim 27, wherein the electrostriction coefficient of the PVDF ribbon is −67.8×10⁻⁹ and the piezoelectric coefficient of the PVDF ribbon is −58.5 pm/v.

29. The piezoelectricity material of claim 24, wherein the thickness of the at least one the PVDF ribbon ranges from 5 nm to 50 nm.

30. The piezoelectricity material of claim 24, wherein the thickness of the at least one the PVDF ribbon ranges from 1 um to 1000 um.
